(19) United States
(12) Patent Application Publication
(10) Pub. No.: US 2013/0009191 A1
(43) Pub. Date: Jan. 10, 2013

(54) SURFACE MOUNTED LED PACKAGE AND MANUFACTURING METHOD THEREFOR

(75) Inventor: You-Fa WANG, Singapore (SG)

(73) Assignee: LITE-ON SINGAPORE PTE. LTD., MIDVIEW CITY (SG)

(21) Appl. No.: 13/175,947

(22) Filed: Jul. 4, 2011

(51) Int. Cl. H01L 33/62; H01L 33/48

(52) U.S. Cl. 257/99; 438/26; 257/E33.066

(57) ABSTRACT

A surface mounted LED package includes an insulated body, a first conductive part, a second conductive part, a LED chip and a bonding wire. The insulated body has a receiving portion and a bond-pad island. The receiving portion is formed with an inner side wall and a flat bottom. The bond-pad island is formed with a bonding plane. The first conductive part has a LED chip and a first solder pin extended to an outer surface of the insulated body. The second conductive part has a second contacting portion and a second solder pin extended to an outer surface of the insulated body. The LED chip is disposed on the second contacting portion. The bonding wire connects the LED chip to the first contacting portion. The present application further provides a manufacturing method for surface mounted LED package.

### BACKGROUND OF THE INVENTION

1. Field of the Invention

The instant disclosure is related to a surface mounted (SMT) LED package and manufacturing method thereof, especially to an LED package has flatted solder pins and can be soldered on a substrate or PCB by Surface Mounted Technology.

2. Description of Related Art

Surface mounted LED has been popularly used as proximity sensor, which has been applied in mobile phone, TV or portable mobile device for sensing the presence of user. To get a longer detecting distance, the surface mounted LED needs smaller beam angle and higher intensity. Therefore, the surface mounted reflection LED is developed to meet the above-mentioned requirements.

Referring to FIG. 1, a conventional surface mounted LED package has an insulated body 9, which including a bowl-shaped receiving portion 92 and a pad setting area 920 located outside the receiving portion 92. The pad setting area 920 is concaved outwardly and downwardly from an inner surface of the receiving portion 92 of the insulated body 9. The bowl-shaped receiving portion 92 is designed for beam lighting. One end of a metallic frame is extended into the pad setting area 920 to form a bond pad, the other end is extended beyond the insulated body 9 to form an electrode (not shown).

The conventional technology has some points needed to improve. First, the pads are located outside the receiving portion 92, such structure needs a longer bonding wire 95. In the meantime, it causes the potential reliability issues. For example, the bonding wire 95 may be higher then the top surface of the insulated body 9 and it is easily exposed in the air. Further, the bonding wire 95 is easily to touch a metallic coating layer formed on an inner surface of the receiving portion 92 to cause a short circuit. Besides, the width of the pad setting area 920 is enlarged, which correspondingly causes a larger package size.

Therefore, it is necessary to propose a novel electrical connector to overcome the above-mentioned problems.

### SUMMARY OF THE INVENTION

The instant disclosure provides a surface mounted LED package, to shorten the length of bonding wire, and lower the height of the bonding wire to reduce the problems of potential reliability issues, and further, the total package size is reduced.

In order to achieve the above objectives, the instant disclosure is to provide a surface mounted LED package, including an insulated body, a first conductive part, a second conductive part, a LED chip and a bonding wire. The insulated body has a receiving portion concaved from a top surface thereof and a bond-pad island located in the receiving portion. The receiving portion has a inner side wall formed therein and a planar bottom surface in an interior thereof. The bond-pad island is partially protruded from the inner side wall of the receiving portion toward the interior thereof and has a conducting plane formed thereon. The first conductive part includes a first contacting portion disposed on the conducting plane and a first solder pin extended to an outer surface of the insulated body. The second conductive part includes a second contacting portion disposed a bottom surface of the receiving portion and a second solder pin extended to an outer surface of the insulated body. The LED chip is disposed on the second contacting portion. The bonding wire is electrically connecting the LED chip to the first contacting portion.

In order to achieve the above objectives, one embodiment according to the instant disclosure provides a manufacturing method of surface mounted LED package, including:

forming an insulated body, wherein the insulated body is formed with a concaved receiving portion and a bond-pad island protruded from a surface of the receiving portion toward an interior of the receiving portion;

forming a conductive layer on a surface of the insulated body, wherein the conductive layer covering the receiving portion and extending to an outer surface of the insulated body to form a first solder pin and a second solder pin;

removing a part of the conductive layer to form an isolation gap, wherein the isolation gap crosses through the bond-pad island, the receiving portion and the insulated body, to partitioning the conductive layer into a first conductive part and a second conductive part;

disposing an LED chip on a bottom surface of the receiving portion and on the second conductive part; and

providing a bonding wire, to electrically connect the LED chip to the first conductive part.

Therefore, the instant disclosure has advantages as followed. The bond-pad island of the receiving portion reduces the total structure size then that of the prior art. The bonding wire just extends into the receiving portion, its length is shortened and its height is lowered, so that the cost of bonding wire and the risk of circuit short of bonding wire are reduced. The conductive layer could be used as a reflecting surface of the receiving portion.

For further understanding of the instant disclosure, reference is made to the following detailed description illustrating the embodiments and examples of the instant disclosure. The description is for illustrative purpose only and is not intended to limit the scope of the claim.

### BRIEF DESCRIPTION OF THE DRAWINGS

FIG. 1 is a perspective view of surface mounted LED of prior art;

FIG. 2 is a perspective view of surface mounted LED of the instant disclosure;

FIG. 3 is a cross-sectional view of surface mounted LED of the instant disclosure; and

FIG. 4 is a top view of surface mounted LED of the instant disclosure.

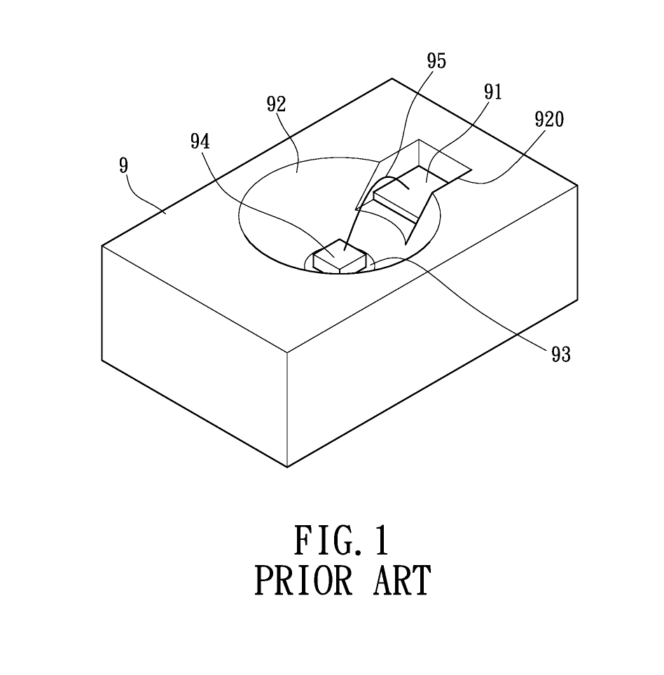

### DETAILED DESCRIPTION OF THE PREFERRED EMBODIMENTS

In order to better understand the objective, structure, characteristics, and effects of the instant disclosure, a description relating thereto will be made with reference to preferred embodiments thereof and the accompanying drawings.

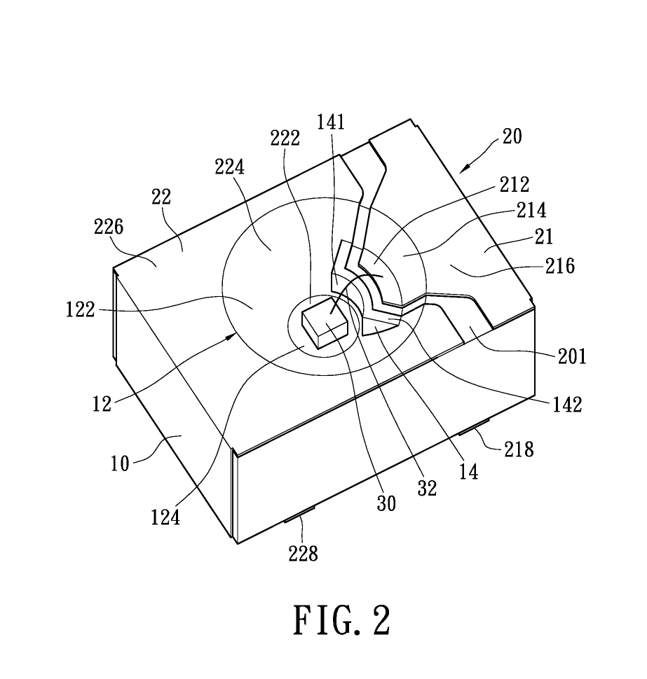

Reference is made to FIG. 2, which is a perspective view of surface mounted LED package according to the instant disclosure. The structure of the instant disclosure is illustrated in relation to the manufacturing method. A surface mounted LED package of the instant disclosure includes an insulated body 10, a conductive layer 20 formed on a surface of the insulated body 10, a LED chip 30, and a bonding wire 32. The conductive layer 20 is extended to an outer surface of the insulated body 10 (in this embodiment is a bottom surface) to form a first solder pin 218 and a second solder pin 228, so that the instant disclosure could be mounted on the PCB (not shown) by surface mounted technology.

The insulated body 10 is made of insulating materials, which can be formed by injecting process. The insulated body 10 has a receiving portion 12 concaved from a top surface thereof and a bond-pad island 14 located in the receiving portion 12. In the embodiment of plastic injecting process, the receiving portion 12 and the bond-pad island 14 could be formed simultaneously with the insulated body 10.

In this embodiment, the receiving portion 12 is substantially bowl-like shaped, and has an inner side wall 122 and a planar bottom surface 124. The receiving portion 12 is concavely formed with an inward cambered surface, which is beneficial to condense light. The LED chip 30 could be disposed on the planar bottom surface 124.

The bond-pad island 14 partially protrudes from the inner surface of the cup-shaped (bowl shaped) receiving portion 12 toward the inner side wall 122, which is substantially wedge-shaped and has a conducting plane 142 formed on a top surface. The conducting plane 142 is shaped as a circular sector. In this embodiment, the bond-pad island 14 has a partial-tubular curve 141 adjacent to the planar bottom surface 124 and a pair of lateral planes (not labeled) connected with the partial-tubular curve 141 and the receiving portion 12. However, the bond-pad island of the present invention is not limited in this embodiment. For example, it could be a circular sector or a part of square column . . . etc.

The conductive layer 20 of the instant disclosure is formed on the surface of the insulated body 10, which could be formed by plating, electroplating or other suitable methods. The receiving portion 12 is covered with the conductive layer 20. An outer surface of the insulated body 10 is also covered with the conductive layer 20. In this embodiment, two opposite sides of the insulated body 10 are covered by the conductive layer 20. When forming the conductive layer 20, the surface area that do not require plating may be masked by suitable shielding materials prior to the plating process, such as peelable film or glue, and removes the sheltering material after plating. According to the outer shape of the insulated body 10, the instant disclosure can form a plurality of receiving portions 12 on a long insulated material. After plating is finished, cutting the insulated material and separating the receiving portions, where the portions being cut form a side surface without plating.

Next, an isolation gap 201 is formed across the conductive layer 20. To form the isolation gap 201, a laser-engraving process could be applied on the conductive layer 20 to remove some part thereof. Alternatively, a sheltering material could be covered on the insulated body 10 before forming the conductive layer 20. In this embodiment, the isolation gap 201 crosses through the bond-pad island 14, the receiving portion 12 and the insulated body 10. Therefore, the conductive layer 20 is partitioned into a first conductive part 21 and a second conductive part 22 for conducting electricity to two electrodes of the LED chip 30 respectively. The conductive layer 20 of the instant disclosure still has other functions, for example, it can be used as a reflection layer of the receiving portion 12 to reflect and condense light.

The first conductive part 21 has a first contacting portion 212, which is formed on the conducting plane 142, and a first solder pin 218, which is extended to an outer side of the insulated body 10. In this embodiment, the first conductive part 21 further includes a first slope portion 214 and a first level portion 216. The first slope portion 214 is extended from the first contacting portion 212 in an oblique manner to an inner side of the receiving portion 12. The first level portion 216 is extended from the top surface of the insulated body 10 by the first slope portion 214. The first level portion 216 partially and outwardly extends and forms the first solder pin 218 which is formed on the outer surface of the insulated body 10. In this embodiment, the first solder pin 218 is disposed on the bottom surface of the insulated body 10. However, the first solder pin could be arranged at different part of the insulated body 10 according to the requirements of the LED package.

The second conductive part 22 has a second contacting portion 222 disposed on the bottom surface of the receiving portion 12, and a second solder pin 228 extended to the outer surface of the insulated body 10. In this embodiment, the second conductive part 22 further includes a second slope portion 224, which is obliquely extended from the first contacting portion 222 to the inner surface of the receiving portion 12, and a second level portion 226, which is extended from the second slope portion 224 to the top surface of the insulated body 10. The second solder pin 228 is extended from the second level portion 226 to the outer surface of the insulated body 10. The second solder pin 228 in this embodiment is disposed on the bottom surface of the insulated body 10. However, the second solder pin could be arranged at different part of the insulated body 10 according to the requirements of the LED package. In this embodiment, the second conductive part 22 has a partial-tubular curve 141 which is partially covered on the bond-pad island 14, so that the partial-tubular curve 141 also condense light and reflect light.

The LED chip 30 is disposed on the second contacting portion 222. In this embodiment, the LED chip 30 has an electrode located at a bottom surface thereof. The electrode could be anode or cathode, which can be fixed by conductive epoxy to electrically connect to the second contacting portion 222. The LED chip 30 has another electrode electrically connecting to the first contacting portion 212 of the first conductive part 21 by a bonding wire 32. Comparing with the conventionally art, the bonding wire 32 of the instant disclosure is totally arranged in the receiving portion 12, not extending beyond receiving portion, and the length could be shortened. However, the two electrodes of the LED chip could all be wiring connects.

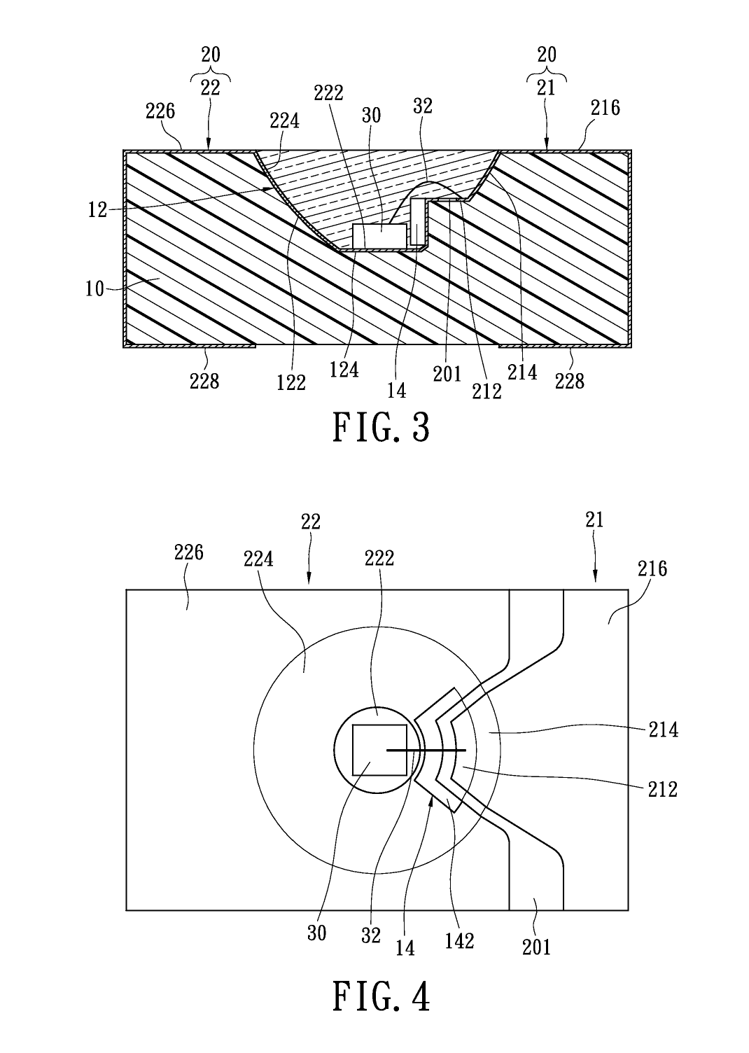

Referring to FIG. 3 and FIG. 4, which are a cross-sectional and a top view of the surface mounted LED package according to the instant disclosure. The conducting plane 142, on the top surface of the bond-pad island 14, is lower than the top surface of the insulated body 10 and closed to the top surface of the LED chip 30. The height of the bond-pad island 142 is about half of the depth of the receiving portion 12. When wire bonding is finished, the bonding wire 32 still is far lower than the top surface of the insulated body 10. The instant disclosure has no disadvantage of exposing the bonding wire like prior art.

In this embodiment, the first conductive part 21 and the second conductive part 22 are formed by the conductive layer 20 plated on the insulated body 10. Because of the isolation gap 201, the conductive layer 20 forms the first conductive part 21 and the second conductive part 22, which are electrically connected two electrodes of the LED chip 30 respectively. The conductive layer 20 works to reflect and condense lights.

To achieve the above-mentioned structure, the instant disclosure provides a method for manufacturing the surface mounted LED package, including the steps as followed.

First, the insulated body 10 is formed, wherein the insulated body 10 is formed with a concave-shaped receiving portion 12 and the bond-pad island 14 is protruded from an inner wall of the receiving portion 12. One embodiment, the receiving portion 12 is formed with the bowl-shaped inner side wall 122 and the planer bottom surface 124.

Next, the conductive layer 20 is formed on the surface of the insulated body 10, which covers the receiving portion 12 and extends to the outer surface of the insulated body 10 to form the first solder pin 218 and the second solder pin 228. A preferred method to form the conductive layer 20 is plating and is described in detail as followed. The conductive layer 20 is covered on the top surface and two side surfaces of the insulated body 10 and extended to the bottom surface of the insulated body 10. The first solder pin 218 and the second solder pin 228 are formed on the bottom surface of the insulated body 10.

Then, a part of the conductive layer 20 is removed to form an isolation gap 201. The isolation gap 201 crosses through the bond-pad island 14, the receiving portion 12 and the insulated body 10, so that the conductive layer 20 is divided as the first conductive part 21 and the second conductive part 22. A preferred way to form the isolation gap 201 can be laser engraving process and described in detail as followed. The first conductive part 21 has the first contacting portion 212 formed on the top surface of the bond-pad island 14, and the second conductive part 22 has the second contacting portion 222 formed on bottom surface 124 of the receiving portion 12.

Next, an LED chip 30 is disposed on the bottom surface of the receiving portion 12 and on the second conductive part 22. In detail, the LED chip 30 is disposed on the bottom surface 124 of the receiving portion 12 and on the second contacting portion 222.

Finally, a bonding wire 32 is provided to connect the LED chip 30 with the first conductive part 21. In detail, is to connect to the first contacting portion 212 of the first conductive part 21.

To sum up, the instant disclosure has the following disadvantages and features as followed. A bond-pad island is formed in the receiving portion, so that the LED package has a size smaller than prior art. The bonding wire is only extended into the receiving portion, the length is shortened and the height is lowered. Not only the cost of bonding wire is reduced, but also the possibility of outside-exposed and the risk of short are lowered. The conductive layer can be used as a reflective layer of the receiving portion, and a circuit to connect two electrodes to the power.

The description above only illustrates specific embodiments and examples of the instant disclosure. The instant disclosure should therefore cover various modifications and variations made to the herein-described structure and operations of the instant disclosure, provided they fall within the scope of the present invention as defined in the following appended claims.

What is claimed is:

1. A surface mounted LED package, comprising:
an insulated body, including a receiving portion concaved from a top surface thereof and a bond-pad island formed in the receiving portion, the receiving portion having an inner side wall formed therein and a planar bottom surface in an interior thereof, wherein the bond-pad island is partially protruded from the inner side wall of the receiving portion toward the interior thereof and has a conducting plane formed thereon;
a first conductive part, including a first contacting portion disposed on the conducting plane and a first solder pin extended to an outer surface of the insulated body;
a second conductive part, including a second contacting portion disposed a bottom surface of the receiving portion and a second solder pin extended to an outer surface of the insulated body;
a LED chip, disposed on the second contacting portion; and
a bonding wire, electrically connecting the LED chip to the first contacting portion.

2. The surface mounted LED package of claim 1, wherein the receiving portion is bowl-shaped, the planar bottom surface has a circular shape.

3. The surface mounted LED package of claim 2, wherein the conducting plane of the bond-pad island is shaped as a circular sector, the bond-pad island has a partial-tubular curve adjacent to the planar bottom surface of the receiving portion, wherein the second conductive part is partially covered on the partial-tubular curve.

4. The surface mounted LED package of claim 3, wherein the conducting plane of the bond-pad island is lower than a top surface of the insulated body and adjacent to a top surface of the LED chip.

5. The surface mounted LED package of claim 1, wherein the first conductive part and the second conductive part are formed in a conductive layer plated on the insulated body, the conductive layer has an isolation gap formed between the first conductive part and the second conductive part, wherein the isolation gap crosses through the conducting plane of the bond-pad island.

6. The surface mounted LED package of claim 1, wherein the conductive layer is covered on the receiving portion and a top surface and two side surfaces of the insulated body, and extends to a bottom surface of the insulated body, wherein the first conductive part and the second conductive part are formed on the bottom surface of the insulated body.

7. A method for manufacturing surface mounted LED package, comprising:
forming an insulated body, wherein the insulated body is formed with a concaved receiving portion and a bond-pad island protruded from a surface of the receiving portion toward an interior of the receiving portion;
forming a conductive layer on a surface of the insulated body, wherein the conductive layer covering the receiving portion and extending to an outer surface of the insulated body to form a first solder pin and a second solder pin;
removing a part of the conductive layer to form an isolation gap, wherein the isolation gap crosses through the bond-pad island, the receiving portion and the insulated body, to partitioning the conductive layer into a first conductive part and a second conductive part;
disposing an LED chip on a bottom surface of the receiving portion and on the second conductive part; and
providing a bonding wire, to electrically connect the LED chip to the first conductive part.

8. The method for manufacturing Surface mounted LED package of claim 7, further comprising a step of covering the conductive layer on a top surface and two sides of the insulated body, and extending to a bottom surface of the insulated body, to form the first solder pin and the second solder pin on the bottom surface of the insulated body.

9. The method for manufacturing surface mounted LED package of claim 8, wherein the receiving portion is defined by a bowl-shaped inner side wall and a planar bottom surface.

10. The method for manufacturing surface mounted LED package of claim 9, wherein the first conductive part has a first contacting portion formed on a top surface of the bond-pad island, and the second conductive part includes a second contacting portion formed on a bottom surface of the receiving portion.

11. The method for manufacturing surface mounted LED package of claim 10, wherein the LED chip is disposed on the bottom surface of the receiving portion and on the second contacting portion.

12. The method for manufacturing surface mounted LED package of claim 11, wherein the bonding wire connects the LED chip to the first contacting portion.

13. The method for manufacturing surface mounted LED package of claim 7, wherein the conductive layer is formed by electroplating process.

14. The method for manufacturing surface mounted LED package of claim 7, wherein the isolation gap is formed by laser engraving process.
